(19) United States
(12) Patent Application Publication
(10) Pub. No.: US 2010/0097607 A1
(43) Pub. Date: Apr. 22, 2010

(54) Film Thickness Measuring Method and Substrate Processing Apparatus

(76) Inventors: Akira Susaki, Tokyo (JP); Shohei Shima, Tokyo (JP); Yukio Fukunaga, Tokyo (JP); Hideki Tateishi, Tokyo (JP); Junko Mine, Tokyo (JP)

Correspondence Address: WENDEROTH, LIND & PONACK, L.L.P., 1030 15th Street, N.W.,, Suite 400 East, Washington, DC, 20005-1503, US

(21) Appl. No.: 11/989,763

(22) PCT Filed: Aug. 1, 2006
(86) PCT No.: PCT/JP2006/315562

§ 371 Date: Jan. 31, 2008

(30) Foreign Application Priority Data
Aug. 5, 2005 (JP) 2005-227977

(51) Int. Cl. G01B 11/06; C23C 14/52; B05C 11/00; B01J 19/00; G01J 4/00; C23G 1/02

(52) U.S. Cl. 356/369; 204/298.03; 118/712; 422/119; 134/3; 356/630

(57) ABSTRACT

A film thickness measuring method can carry out measurement of a thickness of an oxide film more simply in a shorter time. The film thickness measuring method includes determining a thickness of an oxide film or thin film of a metal or alloy by solely using a phase difference Δ, measured by ellipsometry, based on a predetermined relationship between the phase difference Δ and the thickness of the oxide film or thin film of the metal or alloy.

### TECHNICAL FIELD

The present invention relates to a film thickness measuring method which is useful, for example, for measuring a thickness of an oxide film, formed in a surface of a metal film, prior to removing the oxide film in a semiconductor device manufacturing process. The present invention also relates to a substrate processing apparatus which is useful, for example, for forming embedded interconnects by filling an interconnect material into interconnect recesses, such as trenches and via holes, provided in a surface of a substrate such as a semiconductor wafer.

### BACKGROUND ART

With the progress toward finer semiconductor devices, copper is becoming a common interconnect material these days. Further, various metal materials that have not been conventionally used for semiconductor devices, are now in practical use; for example, cobalt for a gate electrode and tantalum as a barrier metal. Hafnium is being studied for its use for a gate insulating film. These metals, in addition to their use in the form of pure metal, can be used in various forms such as an alloy, an oxide, a nitride, and the like.

It is important that films of these metals or their compounds have an intended composition and an intended thickness. If a metal film is formed normally, due to later product control, an unintended native oxide film can grow in the surface of the metal film. This may increase the resistance or change the thickness of the metal film, which could lower the properties or the reliability of the semiconductor device. For example, in a laminated structure of copper interconnects, if copper oxide is present at the bottoms of via holes bridging upper and lower interconnects, the contact resistance of the copper interconnects will increase and the electromigration resistance will decrease.

Measurement of a thickness of a native oxide film formed in a metal surface has heretofore been practiced by various methods, including optical methods (ellipsometry, light absorption analysis, etc.), cross-section observation (with transmission electron microscope (TEM), scanning electron microscope (SEM), etc.), electrical measurements (with electrical capacity, eddy current, etc.), and depth profiling (glow discharge spectroscopy (GDS), secondary ion mass spectrometry (SIMS), etc.). Of these, optical measuring methods, which can measure a film thickness with high sensitivity in a nondestructive manner, are most commonly used in actual manufacturing processes. Especially for measurement of a thickness of an ultrathin film having a thickness of the order of several nm to several tens of nm, ellipsometry, which utilizes reflection and interference of a polarized light, is generally used.

In ellipsometry, a phase difference Δ between the p component and the s component of a reflecting-polarized light, and an amplitude reflectance ratio tan Ψ are obtained as measured values. A film thickness “d” is calculated from the phase difference Δ, the amplitude reflectance ratio tan Ψ, incidence angle θ of light, wavelength λ of light, refractive index “ns” of the substrate and refractive index “nf” of the thin film.

### DISCLOSURE OF INVENTION

When a thickness “d” of a film is calculated by single-wavelength ellipsometry, the refractive index “nf” of the film needs to be known in advance. However, the refractive index of a native metal oxide film can differ significantly between a thin film and a thick film. Further, the refractive index of a film may change with the growth of the film. In view of this, spectroscopic ellipsometry, which changes the wavelength λ of irradiating light, is currently used widely. Spectroscopic ellipsometry, which also calculates the refractive index “ns” of a substrate in addition to a thickness “d” of a film, necessitates a spectroscopic instrument for changing the wavelength λ and involves a high-speed complicated numerical calculation for calculating the film thickness “d” and the refractive index “ns” of the substrate. A film thickness measuring device using spectroscopic ellipsometry is thus complicated and large-sized, and incorporation of such film thickness measuring device into a semiconductor manufacturing apparatus considerably increases the apparatus cost. Therefore, such a film thickness measuring device is generally used independently.

In a process of removing, by reduction or etching, a native oxide film formed in a surface of a surface film of a substrate or a process of intentionally oxidizing a surface of a surface film of a substrate, if the substrate is taken out of a processing chamber having a vacuum or inert gas atmosphere, and exposed to air, the film surface will be oxidized by the oxygen in the air. Thus, a thickness of a film before and after processing will not be measured precisely unless film thickness measurement is carried out within a processing chamber. For example, in an oxide film removal processing as carried out prior to the formation of a barrier metal film by CVD, determination as to whether the removal of oxide film is complete is of importance. In case an independent film thickness measuring device is used, the substrate must be taken out into the air for film thickness measurement. Accordingly, a thickness of an oxide film cannot be measured precisely.

The present invention has been made in view of the above situation in the background art. It is therefore an object of the present invention to provide a film thickness measuring method which can carry out measurement of a thickness of an oxide film more simply in a shorter time. It is also an object of the present invention to provide a substrate processing apparatus which, in carrying out various processings, such as cleaning, of a substrate, can measure a thickness of a surface oxide film of the substrate without taking the substrate out of the apparatus.

In order to achieve the above objects, the present invention provides a film thickness measuring method comprising determining a thickness of an oxide film or thin film of a metal or alloy by solely using a phase difference Δ, measured by ellipsometry, based on a predetermined relationship between the phase difference Δ and the thickness of the oxide film or thin film of the metal or alloy.

When a phase difference Δ is measured by using single-wavelength ellipsometry, the measured phase difference Δ is approximately proportional to a thickness of an oxide film or a thin film when the film thickness is in the range of several nm to several tens of nm. Accordingly, by determining the relationship (proportional relationship) between phase difference Δ and a thickness of an oxide film or a thin film in advance, the thickness of the oxide film or thin film, which is in the range of several nm to several tens of nm, can be determined more simply in a shorter time by solely using a phase difference Δ measured by ellipsometry.

The metal or alloy may comprise copper. In forming copper interconnects by, for example, a damascene process, a thickness of a copper oxide film formed in a surface of copper or a copper alloy may be measured before removing the copper oxide film. This makes it possible to terminate the removal processing upon complete removal of the copper oxide film, thereby preventing an increase in the contact resistance of copper interconnects and a decrease in the electromigration resistance.

The metal or alloy may comprise at least one element selected from the group consisting of silver, gold, platinum, iron, cobalt, nickel, aluminum, tantalum, ruthenium, titanium, tungsten, hafnium, palladium, lead, indium and silicon.

Preferably, the thickness of the oxide film or thin film is not more than 20 nm.

The present invention also provides a substrate processing apparatus including a film thickness measuring device for determining a thickness of a oxide film or thin film of a metal or alloy by solely using a phase difference Δ, measured by ellipsometry, based on a predetermined relationship between the phase difference Δ and the thickness of the oxide film or thin film of the metal or alloy.

A film thickness measuring device, which measures a thickness of an oxide film or thin film of a metal or alloy by solely using a phase difference Δ as measured by ellipsometry, has a relatively simple structure, can be made small-sized and lightweight, and can be incorporated into a substrate processing apparatus at a low cost.

In a preferred aspect of the present invention, the substrate processing apparatus is a gas cleaning apparatus for carrying out heat treatment of a surface oxide film of a substrate by using an organic acid gas.

By incorporating the present film thickness measuring device into a gas cleaning apparatus for carrying out heat treatment with an organic acid gas, and measuring a thickness of an oxide film with the film thickness measuring device before or during heat treatment of the oxide film, the need to carry out excessive heat treatment of the oxide film with an organic acid gas can be eliminated. By thus applying the present invention to removal, by heat treatment with an organic acid gas, of, e.g., an oxide film (copper oxide film) formed in a surface of copper as an interconnect material, it becomes possible to reduce damage to copper interconnects, enhance the reliability of the resulting semiconductor device and decrease the amount of the organic acid gas used.

In a preferred aspect of the present invention, the substrate processing apparatus further includes a film forming apparatus selected from a CVD apparatus, a PVD apparatus and an ALD apparatus.

In a preferred aspect of the present invention, the substrate processing apparatus further includes an oxidizing apparatus for oxidizing a substrate surface.

By determining a thickness of an oxide film or a thin film by solely using a phase difference Δ among various optical parameters measurable by ellipsometry, e.g., of the single-wavelength type, according to the present invention, measurement of the oxide film or thin film can be carried out more simply in a shorter time as compared to a conventional common measuring method using ellipsometry, which calculates a thickness of a thin film from phase difference Δ, amplitude reflectance ratio tan Ψ, incidence angle φ of light, wavelength λ of light, refractive index “ns” of the substrate and refractive index “nf” of the thin film. Furthermore, the present film thickness measuring device, when used in particular application, can be made small-sized and lightweight and can be incorporated into a semiconductor manufacturing apparatus, such as a substrate processing apparatus, at a low cost.

### BRIEF DESCRIPTION OF DRAWINGS

FIG. 1 is a schematic diagram illustrating a film thickness measuring device for use in a film thickness measuring method according to an embodiment of the present invention;

FIG. 2 is a graphical diagram showing the relationship of phase difference Δ and amplitude reflectance ratio tan Ψ, both measured by ellipsometry, to the density and the thickness of a copper oxide film, as observed when the copper oxide film grows in a copper surface;

FIG. 3 is a graphical diagram showing the relationship of phase difference Δ and amplitude reflectance ratio tan Ψ, both measured by ellipsometry, to the density and the thickness of a copper oxide film, as observed when the copper oxide film, whose thickness is limited to 0 to 20 nm, grows in a copper surface;

FIG. 4 is a graphical diagram showing a change in phase difference Δ and a change in amplitude reflectance ratio tan Ψ with the actual growth of a native oxide film (copper oxide);

FIG. 5 is a graphical diagram showing a change in phase difference Δ and a change in the thickness of the native oxide film (copper oxide) with the actual growth of the oxide film;

FIG. 6 is a diagram showing a substrate processing apparatus according to an embodiment of the present invention, which is employed as an organic acid gas cleaning apparatus; and

FIG. 7 is a diagram showing a substrate processing apparatus according to another embodiment of the present invention, which is employed as a film forming apparatus.

### BEST MODE FOR CARRYING OUT THE INVENTION

Preferred embodiments of the present invention will now be described with reference to the drawings.

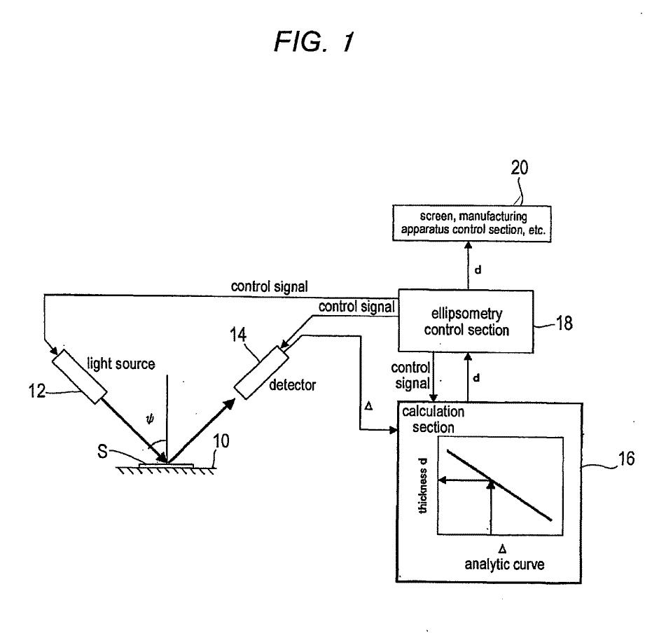

FIG. 1 shows a film thickness measuring device for measuring a thickness of, e.g., a native oxide film, formed in a surface of a substrate, by a film thickness measuring method according to the present invention. As shown in FIG. 1, the film thickness measuring device includes a sample stage 10 for placing thereon a sample S to be measured, e.g., a substrate, a light source 12 for emitting, e.g., He—Ne laser light (wavelength 632.8 nm) toward the sample S placed on the sample stage 10, and a detector 14 for receiving the laser light reflected from the sample S. The emitted laser light has been polarized into a linear polarized light by a polarizing plate provided in the light source 12 and is applied to a surface of the sample S. The linear polarized laser light, when reflected by the surface of the sample S, changes into an elliptical polarized light. The detector 14 measures a phase difference Δ between the polarization components of the reflected laser light by using a polarization plate.

The phase difference Δ detected by the detector 14 is sent to a calculation section 16. The calculation section 16 calculates a thickness “d” of, e.g., an oxide film, formed in the surface of the sample S, from the detected phase difference Δ and a predetermined relationship between phase difference Δ and the thickness of, e.g., the oxide film. The thus-determined film thickness “d” is sent to an ellipsometry control section 18, and is sent from the ellipsometry control section 18 to a control object section 20 such as a screen or a manufacturing apparatus control section. The ellipsometry control section 18 controls with a control signal the light source 12, the detector 14 and the calculation section 16, and carries out film thickness measurement and outputs the results with appropriate timing.

A description will now be made of the principle of determining a thickness of a oxide film or thin film of a metal or alloy by solely using a phase difference Δ, as measured by ellipsometry, based on a predetermined relationship between the phase difference Δ and a thickness of a oxide film or thin film of a metal or alloy. The following description illustrates the case of measuring a thickness of a native copper oxide film that has grown in a surface of a surface copper layer of a substrate.

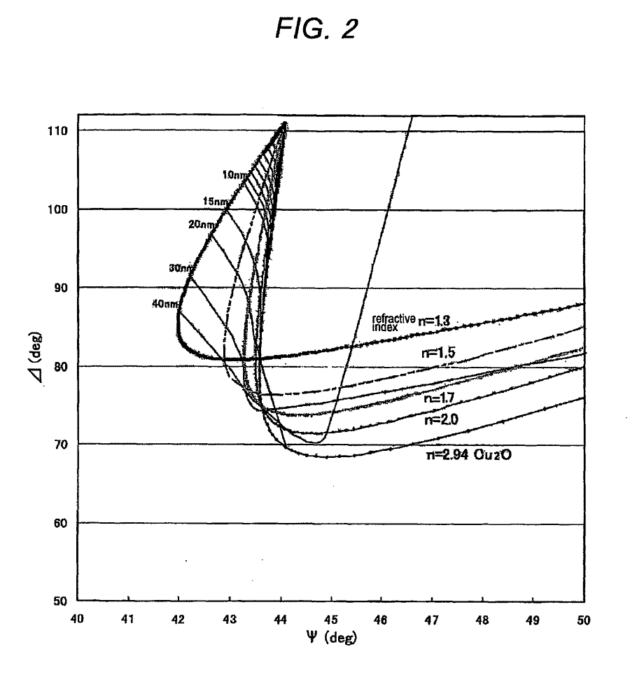

When a native Cu₂O film has grown in the surface of copper, a phase difference Δ and an amplitude reflectance ratio tan Ψ, measured by ellipsometry, change with the density and the thickness of the Cu₂O film, as shown in FIG. 2. As will be appreciated from FIG. 2, the relationship of phase difference Δ and amplitude reflectance ratio tan Ψ, measured by ellipsometry, to the thickness and the density of the oxide film is complicated even for the one type of oxide film. With a general-purpose film thickness measuring device which measures various types of films with various thicknesses, parameters such as the structure, refractive index, etc. of a film need to be determined to a certain extent in advance, and calculation of film thickness is performed through fitting of measured values to a set film structure model. The film thickness measurement processing is thus complicated, and it is necessary for high-speed measurement to use a computer having a high processing power.

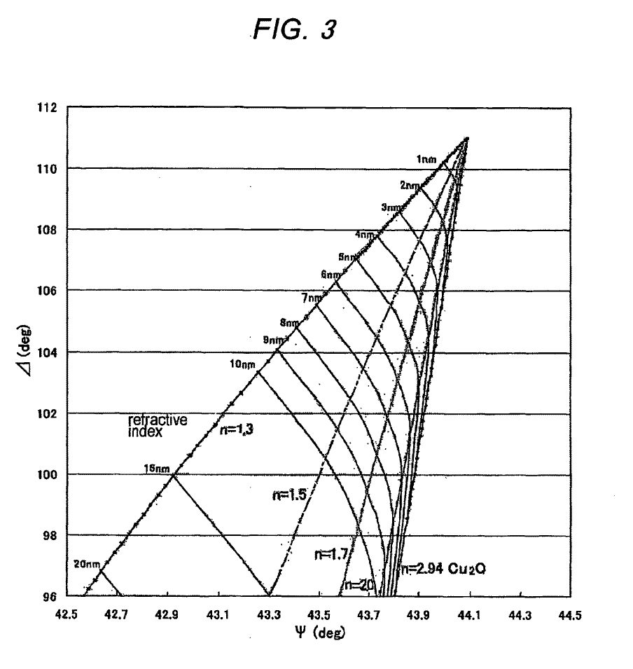

Calculation of a film thickness can be simplified if the type and a thickness of an oxide film to be measured are limited to a certain degree. For example, when a thickness of a copper oxide film formed in a surface of copper is limited to 0-20 nm, the relationship of phase difference Δ and amplitude reflectance ratio tan Ψ, as measured by ellipsometry, to the thickness and the density of the copper oxide film is as shown in FIG. 3. As will be appreciated from the constant-film thickness lines in FIG. 3, unless the refractive index “n” of the oxide film does not change, the relationship of film thickness to phase difference Δ is an approximately linear function, though the film thickness is limited to 0-20 nm.

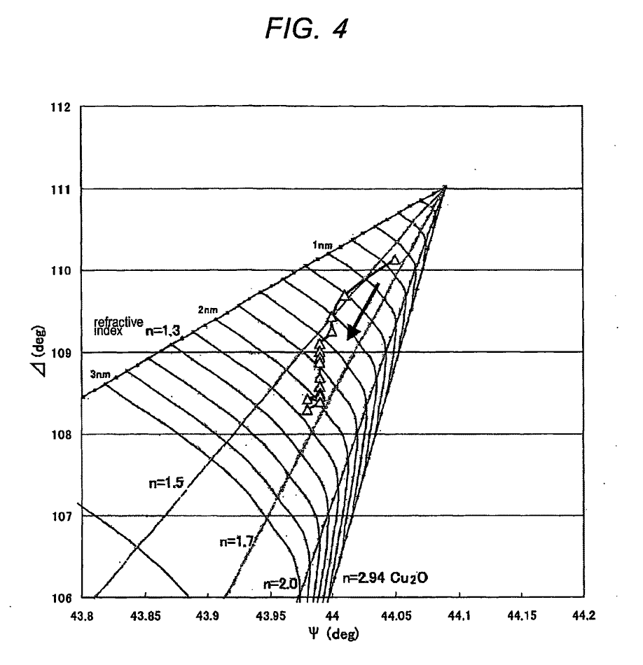

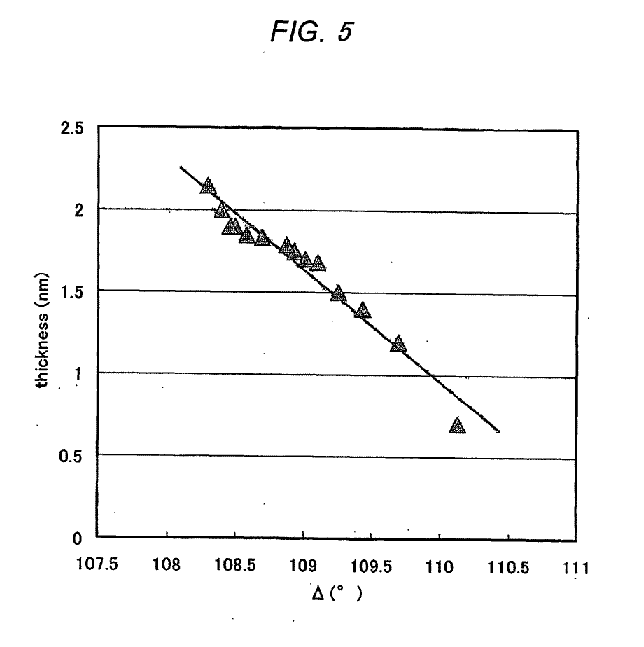

FIG. 4 shows a change in phase difference Δ and a change in amplitude reflectance ratio Ψ with the actual growth of a native oxide film. In particular, a silicon wafer (sample) having a surface copper plated film was washed with 0.5 mol/L aqueous citric acid solution to remove a native oxide film (copper oxide) formed in the surface of copper, and the silicon wafer was then left to stand in the air. An oxide film (copper oxide) then grew in the surface of the silicon wafer, and a phase difference Δ and an amplitude reflectance ratio tan Ψ were measured for the oxide film by means of ellipsometry in a consecutive manner. As shown in FIG. 4, the refractive index “n” changes in the range of 1.5-1.7 as the native oxide film (copper oxide) grows. FIG. 5 shows the relationship between phase difference Δ and the thickness of the native oxide film (copper oxide) of the silicon wafer. As can be seen from FIG. 5, the phase difference Δ changes approximately linearly with an increase in the thickness of the native oxide film; and based on the linear calibration line, the thickness of the native oxide film can be measured only from the phase difference Δ despite the change in the refractive index “n”.

In general, the growth rate and the refractive index of a native oxide film (copper oxide) formed in a surface of a copper film differ depending on the copper film-forming conditions, the pre-oxidation processing conditions, the oxidation conditions, etc. Thus, the relationship between the thickness of the oxide film and phase difference Δ generally is not a linear function as described above. In a mass-production process, however, products, which have been processed under substantially the same conditions, are processed in the same manufacturing apparatus. A measuring object is thus limited practically, which makes it possible to calculate the thickness of the measuring object only from a phase difference Δ. In the case of change to a different measuring object, a calibration line (curve) for the measuring object may be prepared in advance.

When the above silicon wafer was left to stand in a clean room (at a temperature of 24-25° C. and a humidity of about 30%) without forcible oxidization, such as heating or exposure to an oxidizing atmosphere, the thickness of the native oxide film (copper oxide) formed in the surface of copper was about 2.2 nm after 24 hours. In an actual semiconductor manufacturing process, time control is usually carried out, for example, after polishing, e.g., by CMP, of copper on which surface oxidation is likely to progress, or after the formation of via holes by etching. Accordingly, in the case of a copper oxide film formed in a surface of copper, it will be sufficient if the film thickness up to 20 nm can be measured, and a sufficient control of the film thickness is possible only with phase difference Δ.

As described hereinabove, a phase difference Δ, as measured by single-wavelength ellipsometry, is approximately proportional to a thickness of an oxide film, such as copper oxide, when a film thickness is not more than several tens of nm. Accordingly, by determining the relationship (proportional relationship) between phase difference Δ and a thickness of an oxide film in advance, the thickness of the oxide film, which is not more than several tens of nm, can be determined more simply in a shorter time by solely using a phase difference Δ as measured by ellipsometry, i.e., without further using amplitude reflectance ratio tan Ψ, incidence angle φ of light, wavelength λ of light, refractive index “ns” of the substrate and refractive index “nf” of the thin film as in the conventional measuring method utilizing ellipsometry.

Though the case of measuring a thickness of a copper oxide film formed in a surface of copper has been described, it is also possible to measure a thickness of an oxide film formed in a surface of a copper alloy. A phase difference Δ as measured by ellipsometry is approximately proportional also to a thickness of an oxide film or a thin film formed in a surface of a metal or an alloy comprising at least one element of silver, gold, platinum, iron, cobalt, nickel, aluminum, tantalum, ruthenium, titanium, tungsten, hafnium, palladium, lead, indium and silicon, provided the film thickness is not more than several tens of nm. Accordingly, by determining the relationship (proportional relationship) between phase difference Δ and the thickness of the oxide film or the thin film in advance, the thickness of the metal or alloy oxide film, which is not more than several tens of nm, can be determined more simply in a shorter time by solely using a phase difference Δ as measured by ellipsometry.

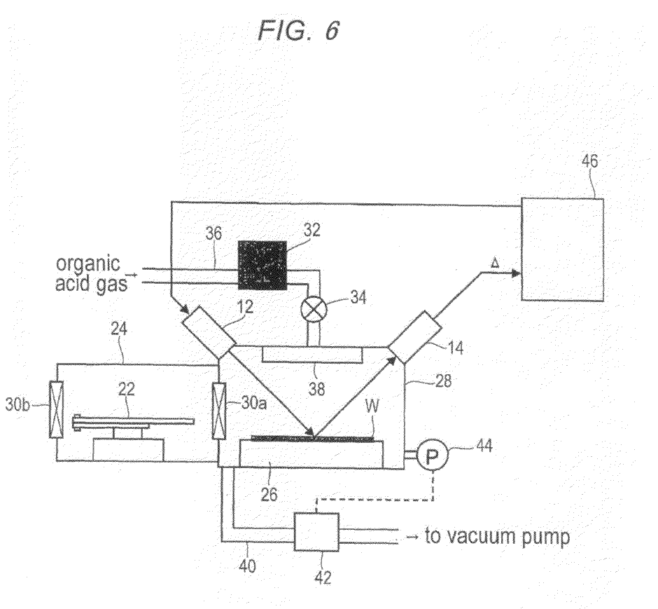

FIG. 6 shows a substrate processing apparatus according to an embodiment of the present invention, which is employed as an organic acid gas cleaning apparatus for carrying out heat treatment of a copper oxide film formed in a surface of a copper film of a substrate by using an organic acid gas to remove the copper oxide film. The gas cleaning apparatus (substrate processing apparatus) includes a transport chamber 24 housing therein a transport robot 22, and an airtight processing chamber 28 having in its interior a substrate stage 26 for placing thereon and heating a substrate W. Gate valves 30a, 30b are provided between the transport chamber 24 and the processing chamber 28, and at the inlet of the transport chamber 24.

At the top of the processing chamber 28 is provided a gas supply head 38 which is connected to an organic acid gas supply line 36, extending from an organic acid supply source (not shown), for supplying an organic acid, such as formic acid or acetic acid, and having on its way a mass flow controller 32 and a gas supply valve 34. Further, an exhaust line 40, connecting to a vacuum pump (not shown), is connected to the processing chamber 28. A pressure control section 42 is provided in the exhaust line 40 and controlled by a signal from a pressure gauge 44 which detects the pressure in the processing chamber 28.

The gas cleaning apparatus is to supply a vaporized organic acid gas (mainly formic acid gas) to the surface of the heated substrate W to cause the organic acid gas to react with copper oxide in the surface of the substrate W, thereby removing the copper oxide from the surface of the substrate W and changing the surface of the substrate W into metallic copper. The gas cleaning apparatus removes, for example, a native oxide film (copper oxide) which is formed in a surface of copper when the copper is exposed in a process of forming copper interconnects having a damascene structure. A substrate is exposed to the air, for example, during the period from the formation of via holes until the formation of a barrier metal film, because of transfer of the substrate from an etching apparatus to a film forming apparatus (PVD apparatus, ALD apparatus, or the like). A copper oxide film therefore grows in the surface of copper at the bottoms of via holes. By incorporating the gas cleaning apparatus into a film forming apparatus, and removing copper oxide and changing the substrate surface into metallic copper prior to the formation of a barrier metal film, for example, a rise in the contact resistance of copper interconnects can be prevented, thus preventing lowering of the reliability of the interconnects.

When removing copper oxide in a substrate surface with an organic acid gas, the copper oxide is reduced and, at the same time, is etched, with the etched copper atoms scattering around. If the gas cleaning is continued even after the copper oxide is removed and the substrate surface has changed into metallic copper, the copper surface will roughen. Such damage as scattering of copper atoms and roughening of copper surface can cause deterioration of the performance of the semiconductor device and lowering of the device reliability and, therefore, should be minimized. It is therefore necessary for gas cleaning processing to employ an end point detection mechanism in order to terminate the processing when copper oxide is completely removed.

The gas cleaning apparatus of this embodiment thus incorporates a film thickness measuring device for in-situ measurement of a thickness of a surface oxide film of a substrate. The film thickness measuring device includes, located in the processing chamber 28, a light source 12 for emitting, e.g., He—Ne laser light (wavelength 632.8 nm) toward the substrate W placed on the substrate stage 26, and a detector 14 for receiving the laser light reflected from the substrate W. The emitted laser light has been polarized into a linear polarized light by a polarizing plate provided in the light source 12 and is applied to the surface of the substrate W. The linear polarized laser light, when reflected by the surface of the substrate W, changes into an elliptical polarized light. The detector 14 measures a phase difference Δ between the polarization components of the reflected laser light by using a polarization plate.

The phase difference Δ detected by the detector 14 is sent to a measurement section 46 comprising the calculation section 16 and the ellipsometry control section 18, both shown in FIG. 1. As with the calculation section 16 shown in FIG. 1, the measurement section 46 calculates the thickness “d” of the copper oxide film, formed in the surface of the substrate W, from the detected phase difference Δ and a predetermined relationship between phase difference Δ and the thickness of the copper oxide film (oxide film). As in the embodiment shown in FIG. 1, the thickness “d” thus determined in the measurement section 46 (calculation section 16) is sent to a control object section 20 such as a screen or a manufacturing apparatus control section. The measurement section 46 controls with a control signal the light source 12 and the detector 14, and carries out film thickness measurement and outputs the results with appropriate timing.

In operation, the substrate W having a surface copper film is conveyed by the transport robot 22 onto the substrate stage, 26 in the processing chamber 28, and heated to, e.g., 200° C. Next, an organic acid gas, e.g., formic acid gas, vaporized by a vaporizer, is supplied from the gas supply head 38 to the surface of the substrate W while controlling the gas flow rate at 200 sccm with the mass flow controller 32, thereby reacting the surface copper oxide of the substrate W with the organic acid (e.g., formic acid) and removing the copper oxide from the surface of the substrate W.

While processing the substrate W with the organic acid in this manner, the surface of the substrate W on the substrate stage 26 is irradiated with the polarized laser light emitted from the light source 12 provided in the processing chamber 28. The laser light, which has changed into an elliptical polarized light upon reflection at the surface of the substrate W, is received and dispersed by the detector 14 to determine the phase difference Δ. The supply of the organic acid gas is stopped when the phase difference Δ has reached the value of metallic copper (about −110°), thereby terminating the processing of the substrate with the organic acid gas. It has been confirmed experimentally that in the case of a copper oxide film (native oxide film) having a thickness of about 2 nm (phase difference Δ=about −106°), it takes about 6 seconds for the phase difference Δ to reach the value −110° at a substrate temperature of 200° C., and about 48 seconds at a substrate temperature of 170° C.

The gas cleaning processing can thus be terminated immediately after the copper oxide is removed and the substrate surface has changed into metallic copper. This can minimize damage to the substrate, such as scattering of copper atoms and roughening of the substrate surface, which would cause deterioration of the performance of the semiconductor device and lowering of the device reliability.

Though in the embodiment shown in FIG. 6 the light source 12 and the detector 14 are provided in the processing chamber 28, and the thickness of the copper oxide film (oxide film) is measured in situ, it is also possible to provide the light source 12 and the detector 14 in the transport chamber 24, in a measurement chamber exclusively for measurement, or in another processing chamber, and to measure the thickness of a copper oxide film before or after processing of a substrate. In the case of measuring a thickness of a copper oxide film after processing of a substrate, if the measured phase difference Δ is short of the intended value of metallic copper (−110°), additional processing of the substrate with an organic acid gas may be carried out.

Though in the embodiment shown in FIG. 6 the measurement of the thickness of the copper oxide film is carried out on one point in the surface of the substrate W, it is also possible to carry out measurement of the thickness of the copper oxide film on a number of points in a surface of a substrate W by rotating or moving the substrate W or by moving the light source 12 and the detector 14, according to necessity. For example, a light source, which emits laser light toward a substrate on a transport arm during transport of the substrate, may be provided so that a film thickness distribution along one diameter of the substrate can be measured continuously with the movement of the substrate. Since in this embodiment a single-wavelength laser light is used for film thickness measurement and a thickness of a copper oxide film (oxide film) is calculated only from phase difference Δ, the measurement can be carried out in a short time. Accordingly, measurement of film thickness during transport of a substrate can be carried out without significant lowering of the transport speed.

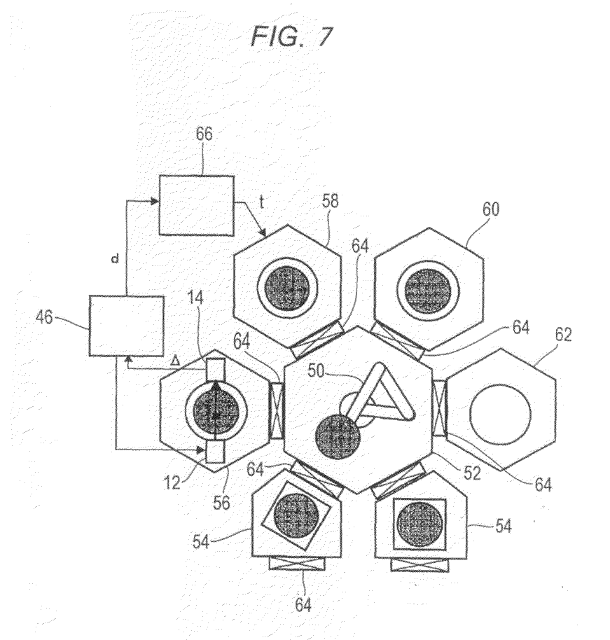

FIG. 7 shows a substrate processing apparatus according to another embodiment of the present invention, which is employed as a film forming apparatus. As shown in FIG. 7, the film forming apparatus (substrate processing apparatus) includes a transport chamber 52 housing a transport robot 50 and disposed in the center of the apparatus and, disposed around the transport chamber 52, two loading/unloading chambers 54, a film thickness measuring device chamber 56, an organic acid gas cleaning chamber 58, a first film forming chamber 60 and a second film forming chamber 62. Gate valves 64 are disposed between the transport chamber 52 and the chambers 54, 56, 58, 60, 62, and at the inlets of the loading/unloading chambers 54, so that the chambers 52, 54, 56, 58, 60, 62 are hermetically sealable.

Similarly to the processing chamber 28 shown in FIG. 6, the film thickness measuring device chamber 56 has in its interior a light source 12 for emitting, e.g., He—Ne laser light (wavelength 632.8 nm) toward a substrate W, and a detector 14 for receiving the laser light reflected from the substrate W. The emitted laser light has been polarized into a linear polarized light by a polarizing plate provided in the light source 12 and is applied to the surface of the substrate W. The linear polarized laser light, when reflected by the surface of the substrate W, changes into an elliptical polarized light. The detector 14 measures a phase difference Δ between the polarization components of the reflected laser light by using a polarization plate. The phase difference Δ detected by the detector 14 is sent to a measurement section 46. The measurement section 46 calculates a thickness “d” of an oxide film, formed in the surface of the substrate W, from the detected phase difference Δ and a predetermined relationship between phase difference Δ and the thickness of the oxide film.

The organic acid gas cleaning chamber 58 has the same construction as the processing chamber 28 shown in FIG. 6, except that a film thickness measuring device is not provided, and the processing time “t” in the chamber 58 is controlled by a signal from an organic acid gas cleaning control section 66. In particular, the film thickness “d” determined by the measurement section 46 is inputted to the organic acid gas cleaning control section 66, and the organic acid gas cleaning control section 66 determines and controls the processing time “t” to process a substrate with an organic acid gas supplied into the organic acid gas cleaning chamber 58.

The first film forming chamber 60 is adapted to form, e.g., a film of Ta, TaN or the like, which serves as a barrier metal for interconnects, on a surface of a substrate, e.g., by PVD. The second film forming chamber 62 is adapted to form, e.g., a copper seed film, which will serve as an electric supply layer in a subsequence copper plating process, on a surface of the barrier metal film formed in the first film forming chamber 60, e.g., by PVD. These film forming chambers may be adapted to form a film by CVD or ALD.

In operation, a substrate having an dielectric film, formed on interconnects of, e.g., copper, in which via holes reaching the surfaces of interconnects have been formed by etching, is transported into the loading/unloading chamber 54. After evacuating the loading/unloading chamber 54, the transport chamber 52 and the film thickness measuring device chamber 56, the substrate in the loading/unloading chamber 54 is transferred by the transport robot 50 via the transport chamber 52 to the film thickness measuring device chamber 56. In the film thickness measuring device chamber 56, the substrate is irradiated with laser light emitted from the light source 12, and a phase difference Δ is measured with the detector 14. The measured phase difference Δ is inputted to the measurement section 46, and the measurement section 46 calculates the thickness “d” of an oxide film formed in the substrate, i.e., a copper oxide film formed in the surface of the copper interconnects exposed at the bottoms of the via holes; from the measured phase difference Δ and a predetermined relationship between phase difference Δ and the thickness of the copper oxide film (oxide film). The thickness “d” is sent to the organic acid gas cleaning control section 66 of the organic acid gas cleaning chamber 58.

Next, the substrate is transferred via the transport chamber 52 to the organic acid gas cleaning chamber 58. The organic acid gas cleaning control section 66 of the organic acid gas cleaning chamber 58 calculates the processing time “t” based on the thickness “d” of the oxide film, and the substrate is cleaned with an organic acid gas for the predetermined processing time “t”. This manner of gas cleaning can remove the oxide film (copper oxide) from the substrate and, in addition, can avoid an excessive cleaning process.

Next, the substrate is transferred via the transport chamber 52 to the first film forming chamber 60, where a film of Ta, TaN or the like, which serves as a barrier metal for interconnects, is formed, e.g., by PVD. After completion of the formation of the barrier metal film, the substrate is transferred via the transport chamber 52 to the second film forming chamber 62, where a copper seed film, which will serve as an electric supply layer in a subsequence copper plating process, is formed on a surface of the barrier metal film, e.g., by PVD. After completion of the formation of the copper seed film, the substrate is returned via the transport chamber 52 to the loading/unloading chamber 54.

By thus carrying out the entire process, from the measurement of a thickness of a oxide film (copper oxide) to the formation of a copper seed film, consistently under vacuum, the growth of a native oxide film in the course of the process can be prevented, and precise control of a film thickness can be performed whereby the organic acid gas cleaning conditions can be always optimized.

A barrier metal film generally has a thickness of several tens of nm, approximating to the film thickness range for which film thickness measurement can be carried out by measuring a phase difference Δ. According to the present apparatus with the film thickness measuring device provided in vacuum, if the relationship between phase difference Δ and a thickness of a barrier metal film is determined in advance, the thickness of the barrier metal film can be monitored for all substrates. This can eliminate the need to carry out film thickness measurement by using a dummy wafer and, in addition, can detect an abnormal film thickness during consecutive processings.

Similarly, also in the case of forming an oxide film in a surface of a substrate by means of an oxidizing apparatus, the thickness of the oxide film can be measured in situ by incorporating a film thickness measuring device into the oxidizing apparatus, or measured in a separate measuring device chamber.

The addition of a film thickness measuring device utilizing ellipsometry to a gas cleaning apparatus can eliminate the need to carry out excessive gas cleaning of a substrate, as described above. This can avoid unnecessary damage to a substrate and can reduce the amount of the organic acid gas used, thus reducing the cost and also reducing the burden on the environment.

Furthermore, film thickness measurement can be carried out for all substrates. This makes it possible to detect an abnormal thickness of an oxide film before processing in a process step, facilitating detection of a problem in the previous process steps.

While incorporation of a film thickness measuring device, which measures, by ellipsometry, a thickness of a copper oxide film formed in a surface of copper, into a substrate processing apparatus, such as a gas cleaning apparatus, has been described, it is also possible to incorporate a film thickness measuring device, which measures, by ellipsometry, a thickness of an oxide film other than copper oxide, formed in a surface of a metal or an alloy, into any desired substrate processing apparatus.

### INDUSTRIAL APPLICABILITY

A film thickness measuring method of the present invention is useful, for example, for measuring a thickness of an oxide film, formed in a surface of a metal film, prior to removing the oxide film in a semiconductor device manufacturing process.

1. A film thickness measuring method comprising:
determining a thickness of an oxide film or thin film of a metal or alloy by solely using a phase difference Δ, measured by ellipsometry, based on a predetermined relationship between the phase difference Δ and the thickness of the oxide film or thin film of the metal or alloy.

2. The film thickness measuring method according to claim 1, wherein the metal or alloy comprises copper.

3. The film thickness measuring method according to claim 1, wherein the metal or alloy comprises at least one element selected from the group consisting of silver, gold, platinum, iron, cobalt, nickel, aluminum, tantalum, ruthenium, titanium, tungsten, hafnium, palladium, lead, indium and silicon.

4. The film thickness measuring method according to claim 1, wherein the thickness of the oxide film or thin film is not more than 20 nm.

5. A substrate processing apparatus comprising:
a film thickness measuring device for determining a thickness of an oxide film or thin film of a metal or alloy by solely using a phase difference Δ, measured by ellipsometry, based on a predetermined relationship between the phase difference Δ and the thickness of the oxide film or thin film of the metal or alloy.

6. The substrate processing apparatus according to claim 5, wherein the substrate processing apparatus is a gas cleaning apparatus for carrying out heat treatment of a surface oxide film of a substrate by using an organic acid gas.

7. The substrate processing apparatus according to claim 5, further comprising a film forming apparatus selected from a CVD apparatus, a PVD apparatus and an ALD apparatus.

8. The substrate processing apparatus according to claim 5, further comprising an oxidizing apparatus for oxidizing a substrate surface.

9. The film thickness measuring method according to claim 2, wherein the thickness of the oxide film or thin film is not more than 20 nm.

10. The film thickness measuring method according to claim 3, wherein the thickness of the oxide film or thin film is not more than 20 nm.

11. The substrate processing apparatus according to claim 6, further comprising a film forming apparatus selected from a CVD apparatus, a PVD apparatus and an ALD apparatus.

12. The substrate processing apparatus according to claim 6, further comprising an oxidizing apparatus for oxidizing a substrate surface.
